(19) United States
(12) Patent Application Publication
(10) Pub. No.: US 2026/0188418 A1
(43) Pub. Date: Jul. 2, 2026

(54) DEVICE AND METHOD FOR GENERATING PARAMETER PAGE LIBRARY OF NAND FLASH MEMORY

(71) Applicant: DOUBLEO CO., LTD., Busan (KR)

(72) Inventors: MyoungHwan Joung, Busan (KR); Wonhee Kim, Busan (KR); Jongmin Kim, Busan (KR)

(73) Assignee: DOUBLEO CO., LTD., Busan (KR)

(21) Appl. No.: 18/861,811

(22) PCT Filed: Jul. 5, 2024
(86) PCT No.: PCT/KR2024/009526

§ 371 Date: Oct. 30, 2024

(30) Foreign Application Priority Data
Jul. 20, 2023 (KR) 10-2023-0094801

(51) Int. Cl. G11C 29/52; G11C 16/26; G11C 16/30

(52) U.S. Cl. CPC G11C 29/52; G11C 16/26; G11C 16/30

(57) ABSTRACT

Proposed are a device and a method for generating a parameter page library of a NAND flash memory and, more specifically, the device and the method capable of generating a parameter page library for each memory chip according to the readout possibility of a parameter page of the corresponding memory in an environment where an internal controller of a NAND flash memory device is unavailable.

### TECHNICAL FIELD

The present disclosure relates to a device and method capable of generating a parameter page library for each memory chip according to the readout possibility of a parameter page of the corresponding memory in an environment where an internal controller of a NAND flash memory device is unavailable.

### BACKGROUND ART

As a semiconductor memory where data can be read and written with electrical signals and the stored data is preserved even after power is cut off, flash memory enables data to be read and written in a specific unit within the memory, but erasing should be performed in block units, so an area containing data is writable only after it is erased.

Such a flash memory can be largely divided into a NOR type, which is a parallel structure, and a NAND type, which is a serial structure. Among them, while the NAND type is slower at reading data than the NOR type, it is faster at writing and erasing since the memory block is divided into multiple pages and the degree of integration per unit is superior to that of NOR, so it is mainly used in SSDs (Solid State Drives), USB memory devices, and the like.

The USB memory device is configured in a way that a flash memory and a controller are separated into each chip form and integrated into one board. When physical damage or failure occurs in the corresponding device, the memory chip corresponding to the flash memory is detached from the device board and mounted on recovery equipment to which a data recovery program is applied, such that the data recovery operation is performed in a way of recombining the dump data by using the parameter data of the memory chip through the data recovery program.

However, even when the data recovery program is used, it should be premised that the controller for controlling the memory operation of the memory chip operates normally in order to access the data area of the memory chip.

Therefore, when there occurs a problem with the controller itself and it does not operate normally, there is a problem in that it is difficult to recover the data of the memory chip.

### DISCLOSURE

### Technical Problem

An objective of the present disclosure is to solve the problem described above and to provide a device and method capable of generating a parameter page library for each memory chip according to the readout possibility of a parameter page of the corresponding memory in an environment where an internal controller of a NAND flash memory device is unavailable.

### Technical Solution

In a device generating a library for a parameter page of a memory chip within the memory device in an environment where a memory controller of a NAND flash-type memory device is unavailable, the device for generating the parameter page library of the NAND flash memory according to one aspect of the present disclosure for achieving the objective described above includes an ID data acquisition module for obtaining ID data of the memory chip in response to executing an ID readout command, by applying an initial setting voltage corresponding to a preset voltage level to a power terminal of the memory chip and then by inputting an initial command value and an initial address value to an input/output terminal of the memory chip, a data loader for loading parameter data stored in a parameter page area by inputting a call command value and a call address value, which are commands for calling the parameter page area of the memory chip, to the input/output terminal when the ID data is obtained, a mode classifier for assigning a mode classification value according to a result of extracting and comparing binary data recorded at a specific byte position of the loaded parameter data with a plurality of preset protocol signature information, a restoration information generator for generating parameter page restoration information by matching a byte-by-byte item value for the corresponding mode classification value and a content of the parameter data in a byte order on the basis of a parameter page length and a byte-by-byte item value information preset corresponding to the assigned-mode classification value, and a library generator for generating and storing a parameter page library by matching and storing the parameter page restoration information, a voltage value applied to the power terminal at the time of obtaining the ID data, and the mode classification value assigned corresponding to the parameter page.

In addition, in a method generating a library for a parameter page of a memory chip within the memory device in an environment where a memory controller of a NAND flash-type memory device is unavailable, the method for generating the parameter page library of the NAND flash memory according to one aspect of the present disclosure for achieving the objective described above includes a step of obtaining ID data of the memory chip in response to executing an ID readout command, by applying an initial setting voltage corresponding to a preset voltage level to a power terminal of the memory chip and then by inputting an initial command value and an initial address value to an input/output terminal of the memory chip, a step of loading parameter data stored in a parameter page area by inputting a call command value and a call address value, which are commands for calling the parameter page area of the memory chip, to the input/output terminal when the ID data is obtained, a step of assigning a mode classification value according to a result of extracting and comparing binary data recorded at a specific byte position of the loaded parameter data with a plurality of preset protocol signature information, a step of generating parameter page restoration information by matching a byte-by-byte item value for the corresponding mode classification value and a content of the parameter data in a byte order on the basis of a parameter page length and a byte-by-byte item value information preset corresponding to the assigned-mode classification value, and a step of generating and storing a parameter page library by matching and storing the parameter page restoration information, a voltage value applied to the power terminal at the time of obtaining the ID data, and the mode classification value assigned corresponding to the parameter page.

### Advantageous Effects

According to the present disclosure, even when the internal controller of the NAND flash memory device is physically damaged or broken and becomes unusable, it is possible to execute the operations and commands of the memory chip, and there is an effect of obtaining parameter data required for data restoration.

In addition, according to the present disclosure, a parameter page library can be constructed for each memory chip, so there is an effect of obtaining information necessary for data recovery of the corresponding memory in a short period of time by using only the memory chip image or data recorded in the memory chip.

The effects of the present disclosure are not limited to the effects described above, and other effects not mentioned will be clearly understood by those skilled in the art from the description of the claims.

### DESCRIPTION OF DRAWINGS

FIG. 1 is a view schematically showing a configuration of a device for generating a parameter page library of a NAND flash memory according to an exemplary embodiment of the present disclosure,

FIG. 2 is a block diagram showing internal configurations of an ID data acquisition module, a memory restoration module, and a library module of FIG. 1 in detail,

FIG. 3 is a view showing an operation timing of a command inputted by an initial command input unit and a data loader of FIG. 2,

FIG. 4 is a view showing a part of a parameter page corresponding to a case of being classified as a first classification value by a mode classifier of FIG. 2,

FIG. 5 is a view showing an example of a parameter page corresponding to a case of being classified into a second classification value by a mode classifier of FIG. 2,

FIG. 6 is a flowchart showing a method for generating a parameter page library of a NAND flash memory according to an exemplary embodiment of the present disclosure,

FIG. 7 is a flowchart showing the step S100 of FIG. 6 in detail,

FIG. 8 is a flowchart showing a data restoration process between the steps S500 and S700 of FIG. 6,

FIG. 9 is a flowchart showing a process of recommending a library after the step S700 of FIG. 6.

### BEST MODE

In a device generating a library for a parameter page of a memory chip within the memory device in an environment where a memory controller of a NAND flash-type memory device is unavailable, the device for generating the parameter page library of the NAND flash memory according to one aspect of the present disclosure for achieving the objective described above includes an ID data acquisition module for obtaining ID data of the memory chip in response in to executing an ID readout command, by applying an initial setting voltage corresponding to a preset voltage level to a power terminal of the memory chip and then by inputting an initial command value and an initial address value to an input/output terminal of the memory chip, a data loader for loading parameter data stored in a parameter page area by inputting a call command value and a call address value, which are commands for calling the parameter page area of the memory chip, to the input/output terminal when the ID data is obtained, a mode classifier for assigning a mode classification value according to a result of extracting and comparing binary data recorded at a specific byte position of the loaded parameter data with a plurality of preset protocol signature information, a restoration information generator for generating parameter page restoration information by matching a byte-by-byte item value for the corresponding mode classification value and a content of the parameter data in a byte order on the basis of a parameter page length and a byte-by-byte item value information preset corresponding to the assigned-mode classification value, and a library generator for generating and storing a parameter page library by matching and storing the parameter page restoration information, a voltage value applied to the power terminal at the time of obtaining the ID data, and the mode classification value assigned corresponding to the parameter page.

In addition, in a method generating a library for a parameter page of a memory chip within the memory device in an environment where a memory controller of a NAND flash-type memory device is unavailable, the method for generating the parameter page library of the NAND flash memory according to one aspect of the present disclosure for achieving the objective described above includes a step of obtaining ID data of the memory chip in response to executing an ID readout command, by applying an initial setting voltage corresponding to a preset voltage level to a power terminal of the memory chip and then by inputting an initial command value and an initial address value to an input/output terminal of the memory chip, a step of loading parameter data stored in a parameter page area by inputting a call command value and a call address value, which are commands for calling the parameter page area of the memory chip, to the input/output terminal when the ID data is obtained, a step of assigning a mode classification value according to a result of extracting and comparing binary data recorded at a specific byte position of the loaded parameter data with a plurality of preset protocol signature information, a step of generating parameter page restoration information by matching a byte-by-byte item value for the corresponding mode classification value and a content of the parameter data in a byte order on the basis of a parameter page length and a byte-by-byte item value information preset corresponding to the assigned-mode classification value, and a step of generating and storing a parameter page library by matching and storing the parameter page restoration information, a voltage value applied to the power terminal at the time of obtaining the ID data, and the mode classification value assigned corresponding to the parameter page.

### MODE FOR INVENTION

The specific details of the present disclosure, including a task to be solved, a means for solving the task, and the effects of the present disclosure, are included in the exemplary embodiments and drawings to be described below. The advantages and features of the present disclosure and a method for achieving them will become clear with reference to exemplary embodiments described below in detail with the accompanying drawings. Throughout the present specification, the same reference numerals refer to the same components.

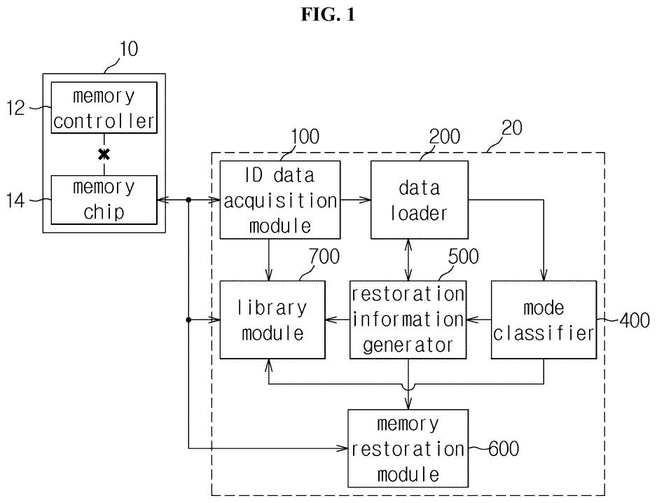

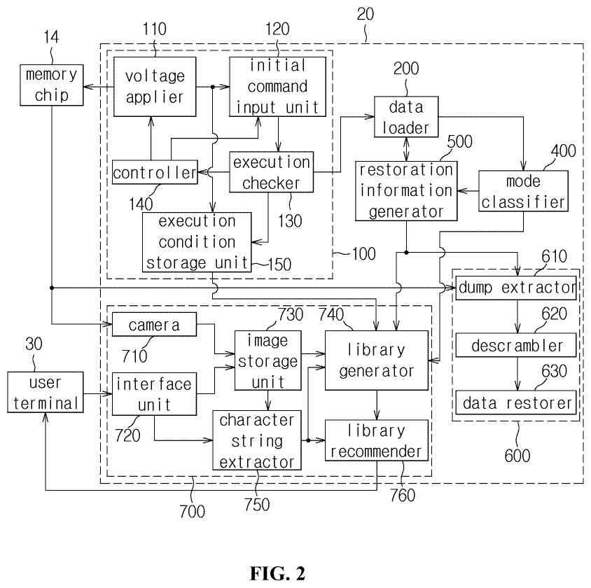

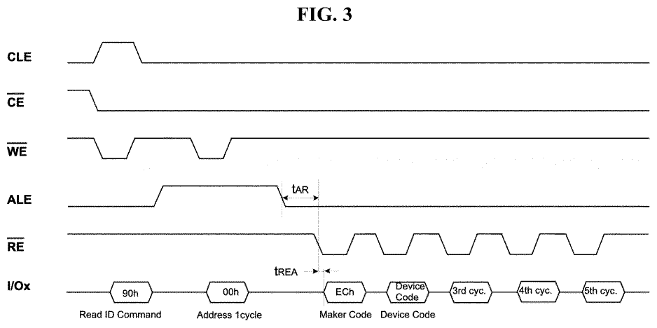

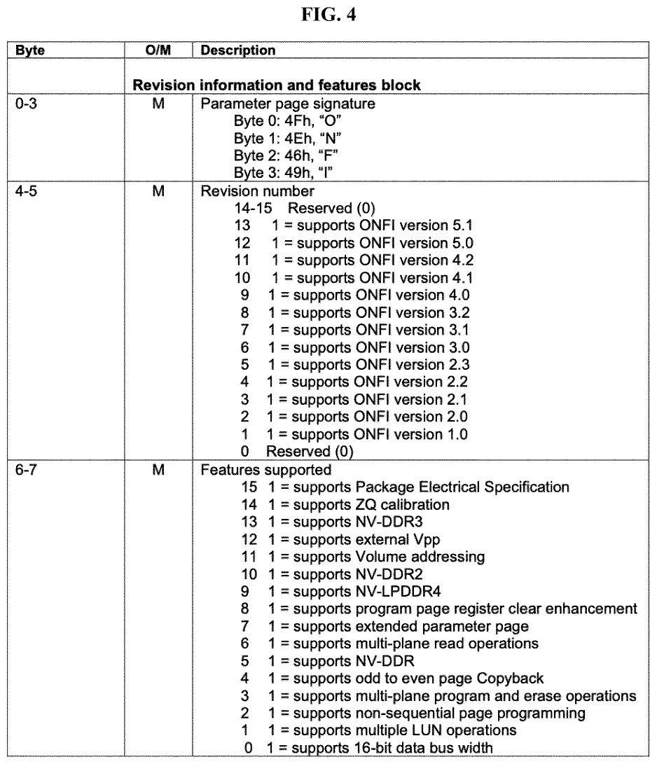

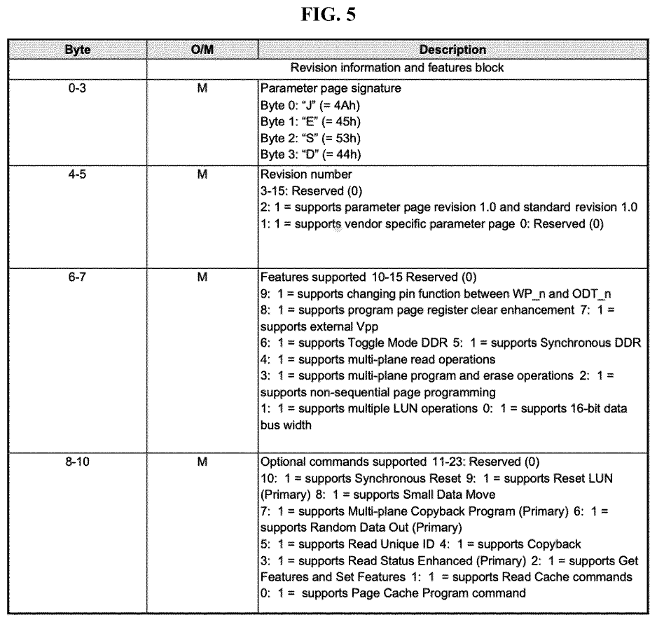

FIG. 1 is a view schematically showing a configuration of a device for generating a parameter page library of a NAND flash memory according to an exemplary embodiment of the present disclosure, FIG. 2 is a block diagram showing internal configurations of an ID data acquisition module, a memory restoration module, and a library module of FIG. 1 in detail, FIG. 3 is a view showing an operation timing of a command inputted by an initial command input unit and a data loader of FIG. 2, FIG. 4 is a view showing a part of a parameter page corresponding to a case of being classified as a first classification value by a mode classifier of FIG. 2, and FIG. 5 is a view showing an example of a parameter page corresponding to a case of being classified into a second classification value by a mode classifier of FIG. 2.

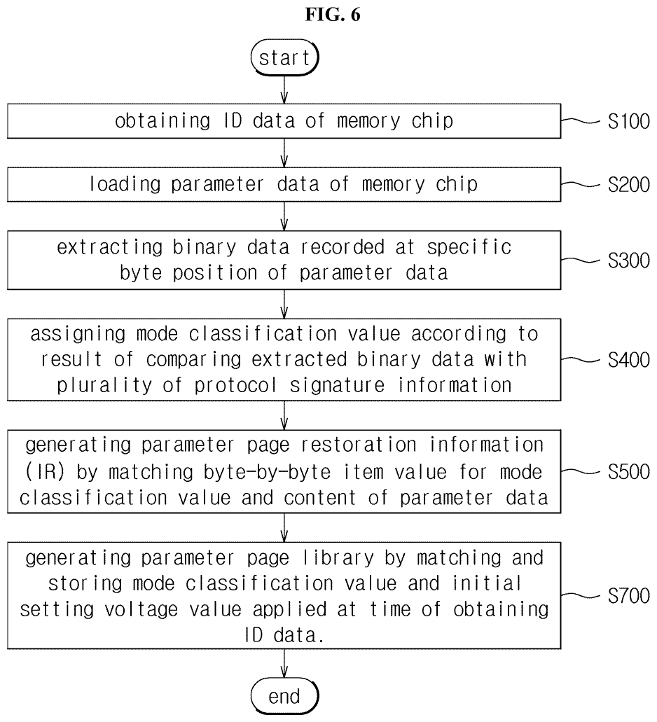

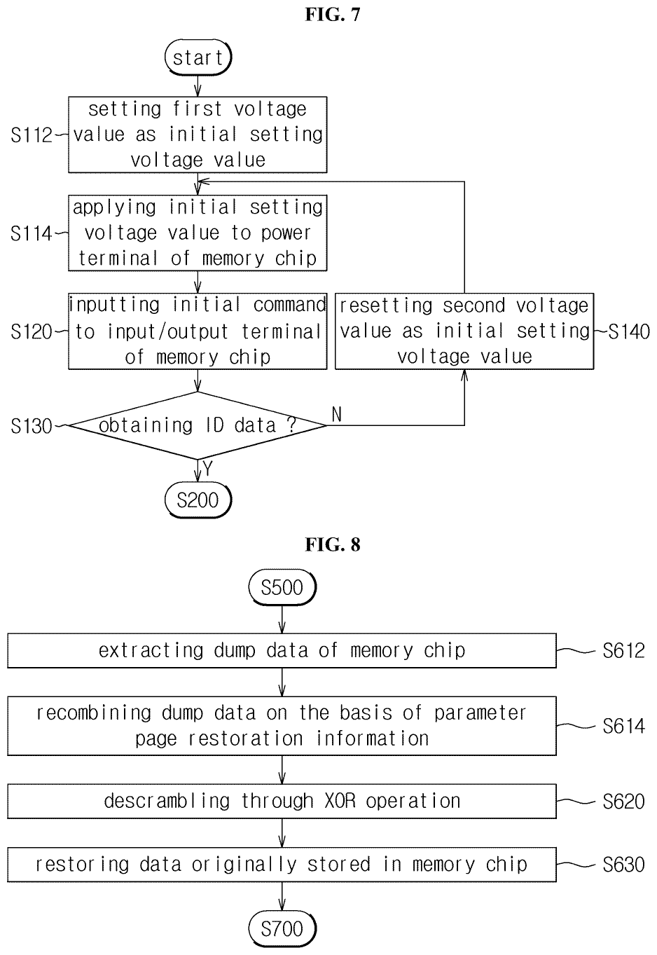

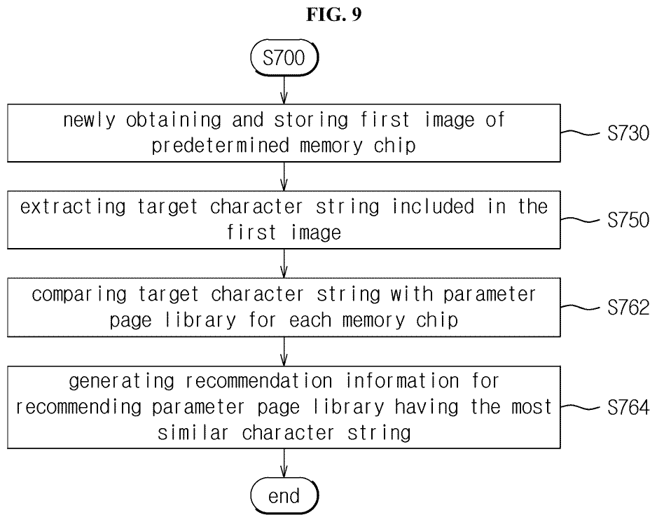

In addition, FIG. 6 is a flowchart showing a method for generating a parameter page library of a NAND flash memory according to an exemplary embodiment of the present disclosure, FIG. 7 is a flowchart showing the step S100 of FIG. 6 in detail, FIG. 8 is a flowchart showing a data restoration process between the steps S500 and S700 of FIG. 6, and FIG. 9 is a flowchart showing a process of recommending a library after the step S700 of FIG. 6.

Hereinafter, a device and method for generating a parameter page library of a NAND flash memory according to a preferred exemplary embodiment of the present disclosure will be described as follows with reference to the drawings described above.

The present disclosure may relate to a device and method for generating a library for a parameter page of a memory chip 14 in the memory device in an environment where a memory controller 12 of a NAND flash-type memory device 10 is unavailable.

First, referring to FIG. 1, the device for generating the parameter page library of the NAND flash memory according to an exemplary embodiment of the present disclosure may be largely configured to include an ID data acquisition module 100, a data loader 200, a mode classifier 400, a restoration information generator 500, a memory restoration module 600, and a library module 700.

The ID data acquisition module 100 may be for obtaining ID data of the memory chip 14 after checking and operating the operation voltage of the memory chip 14.

Herein, the ID data may correspond to unique identification information for distinguishing one memory chip from another memory chip, and may include, for example, information such as a manufacturer ID, a manufacturer's identification code, a device ID, and a device identification code.

The ID data acquisition module 100 may obtain the ID data of the memory chip 14 in response to executing an ID readout command, by applying an initial setting voltage corresponding to a preset voltage level to the power terminal (VDD) of the memory chip 14 and then by inputting an initial command value and an initial address value to the input/output terminal (I/Ox) of the memory chip 14.

Specifically, the ID data acquisition module 100 may include a voltage applier 110, an initial command input unit 120, an execution checker 130, and a controller 140 as shown in FIG. 2.

The voltage applier 110 may set a first voltage value corresponding to one of a plurality of preset voltage levels as the initial setting voltage (V_{S}), and may apply the initial setting voltage (V_{S}) to the power terminal (VDD) of the memory chip 14.

Herein, the initial setting voltage (V_{S}) may refer to a voltage for setting the memory chip to be operable, and a plurality of preset voltage levels may include 1.2V, 1.8V, and 3.3V.

The initial command input unit 120 may input an initial command (C_{I}), including an initial command value and an initial address value, to the input/output terminal (I/Ox) of the memory chip 14 in a state where the initial setting voltage (V_{S}) is applied on the basis of the time when the initial setting voltage (V_{S}) is applied.

Herein, the initial command (C_{I}) may include “90h”, which is an initial command value indicating a readout command of the ID data (Read ID Command) as shown in FIG. 3.

The execution checker 130 may check whether the ID data of the memory chip 14 is obtained in response to executing the ID readout command corresponding to the input of the initial command (C_{I}).

The execution checker 130 may check whether the ID data is loaded according to the initial command value (“90h”).

The controller 140 may control the operations of the voltage applier 110 and the initial command input unit 120 so that the ID data of the memory chip 14 is obtained on the basis of the checking result of the execution checker 130.

When the ID data is not obtained as a checking result of the execution checker 130, the controller 140 may control the voltage applier 110 and the initial command input unit 120 to repeatedly perform an operation of re-inputting the initial command (C_{I}) to the input/output terminal (I/Ox) until the ID data is obtained after resetting as the initial setting voltage (V_{S}) a second voltage value, which has a voltage level different from the currently set initial setting voltage (V_{S}) among the plurality of voltage levels, and applying to the power terminal (VDD).

For example, when the ID data is not obtained as a checking result even when the initial command (C_{I}) is inputted in a state where the first voltage value (1.8 V) is set and applied as the initial setting voltage (V_{S}) of the memory chip 14, the controller 140 may control the voltage applier 110 to reset the second voltage value (3.3V) as the initial setting voltage (V_{S}) and apply the same to the voltage terminal (VDD) and may control the initial command input unit 120 to re-input the initial command (C_{I}) in a state where the reset initial setting voltage (V_{S}) is applied.

At this time, the ID data acquisition module 100 may further include a configuration of an execution condition storage unit 150 for storing the voltage value applied to the voltage terminal (VDD) of the memory chip 14, that is, the initial setting voltage (V_{S}) value, as a voltage condition information that enables the operation and command execution of the memory chip 14, when it is confirmed that the ID data is obtained by the execution checker 130.

The data loader 200 may be for loading the parameter data (D_{P}) of the memory chip 14 after checking whether the ID data is obtained.

When the ID data is obtained as a checking result of the execution checker 130, the data loader 200 may load the parameter data (D_{P}) stored in the parameter page area by inputting a command (C_{P}) for calling the parameter page area of the memory chip 14 to the input/output terminal (I/Ox) of the memory chip 14.

Herein, the command (C_{P}) for calling the parameter page area may include “ECh”, a call command value indicating a call command for a parameter page including a manufacturer code (Maker Code) and a device code as shown in FIG. 3.

The mode classifier 400 may be for determining a mode classification value (M) for the memory chip 14 on the basis of protocol information included in the parameter data (D_{P}).

The mode classifier 400 may extract binary data recorded at a specific byte position of the parameter data (D_{P}) loaded by the data loader 200.

In this case, the binary data extracted by the mode classifier 400 may be preferably first to fourth-byte data of the parameter data (D_{P}).

Meanwhile, the mode classifier 400 may convert the extracted binary data into an ASCII-based character string.

In this case, the mode classifier 400 may convert the first-byte data, the second-byte data, the third-byte data, and the fourth-byte data of the parameter data (D_{P}) into a first character string (S1), a second character string (S2), a third character string (S3), and a fourth character string (S4), respectively.

The mode classifier 400 may assign a mode classification value (M) according to a result of comparing the extracted binary data or the converted character string data with a plurality of preset protocol signature information.

Herein, the plurality of protocol signature information may include “ONFI”, an acronym for Open NAND Flash Interface working group (Open NAND Flash Interface), and “JESD”, an acronym for a memory standard document (JEDEC standard) published by JEDEC (Joint Electron Device Engineering Council).

When using binary data as a target for comparison, the mode classifier 400 may compare the first-byte data of the parameter data (D_{P}) with the respective binary value converted from the first character string (“O”, “J”) of the protocol signature information, compare the second-byte data of the parameter data (D_{P}) with the respective binary value converted from the second character string (“N”, “E”) of the protocol signature information, compare the third-byte data of the parameter data (D_{P}) with the respective binary value converted from the third character string (“F”, “S”) of the protocol signature information, and compare the fourth-byte data of the parameter data (D_{P}) with the respective binary value converted from the fourth character string (“I”, “D”) of the protocol signature information.

When using the character string data as a target for comparison, the mode classifier 400 may compare the first character string (S1) with “O” and “J” which are the first character string of the protocol signature information, compare the second character string (S2) with “N” and “E” which are the second character string of the protocol signature information, compare the third character string (S3) with “F” and “S” which are the third character string of the protocol signature information, and compare the fourth character string (S4) with “I” and “D” which are the fourth character string of the protocol signature information.

According to the comparison result described above, the mode classifier 400 may assign the mode classification value (M) as a first classification value when corresponding to “ONFI”, a second classification value when corresponding to “JESD”, or a third classification value when corresponding to neither the first classification value nor the second classification value.

The restoration information generator 500 may generate the parameter page restoration information (I_{R}) by matching the byte-by-byte item value for the corresponding mode classification value (M) with the contents of the parameter data (D_{P}) loaded by the data loader 200 in a byte order on the basis of the parameter page length and the byte-by-byte item value information preset corresponding to all the mode classification values (M) assigned by the mode classifier 400.

In this case, a DB may be further included that distinguishes by classification value and stores table data of the parameter page corresponding to the first classification value (ONFI) shown in FIG. 4 and table data of the parameter page corresponding to the second classification value (JESD) shown in FIG. 5.

Herein, the table data of the parameter page may be table data in which the byte number and the item value information may be mapped and stored, and the parameter page length may be determined by the last byte number corresponding to the lowest item of the corresponding table.

For example, the last byte number for the lowest item of the parameter page table for “ONFI” may be “767” and the last byte number for the lowest item of the parameter page table for “JESD” may be “1535”, so the parameter page lengths of the first classification value (ONFI) and the second classification value (JESD) may be different.

The memory restoration module 600 may be for restoring data originally stored in the memory chip 14 on the basis of the parameter page restoration information (I_{R}).

The memory restoration module 600 may restore data originally stored in the memory chip 14 by recombining the dump data of the memory chip 14 on the basis of the parameter page restoration information (I_{R}).

As shown in FIG. 2, the memory restoration module 600 may be composed of a dump extractor 610, a descrambler 620, and a data restorer 630, wherein the dump extractor 610 performs an operation of extracting dump data of the memory chip 14, the descrambler 620 performs an operation of descrambling through an XOR operation after recombining the extracted dump data on the basis of the parameter restoration information (I_{R}), and the data restorer 630 performs an operation of restoring data originally stored in the memory chip 14 on the basis of the descrambled data.

A library module 700 may be for constructing a library for the parameter page information of the memory chip 14.

Specifically, the library module 700 may include a camera 710, an interface unit 720, an image storage unit 730, a character string extractor 750, a library generator 740, and a library recommender 760, as shown in FIG. 2.

The library generator 740 may generate and store the parameter page library (L) by matching and storing the parameter page restoration information (I_{R}), the initial setting voltage value (V_{S}) applied to the power terminal (VDD) at the time of obtaining the ID data of the memory chip 14, and the mode classification value (M) assigned corresponding to the parameter page.

The camera 710 may obtain an image by photographing the front or the bottom of a first memory chip and transmit the same to the image storage unit 730.

The interface unit 720 may receive as input the front or the bottom image of the first memory chip from the user through the user terminal 30 and transmit the same to the image storage unit 730.

The image storage unit 730 may obtain and store the image transmitted from the camera 710 or the interface unit 720.

The character string extractor 750 may extract a character string included in the image stored in the image storage unit 730 by using a preset character string extraction algorithm.

In this case, the library generator 740 may generate and store the parameter page library (L) for each memory chip by matching and storing the parameter page restoration information (I_{R}) described above, the initial setting voltage value (V_{S}), the image stored corresponding to the first memory chip along with the mode classification value (M), and the character string value extracted therefrom.

The library recommender 760 may be for recommending a parameter page library of a memory chip similar to a newly stored memory chip image on the basis of the pre-stored parameter page library.

When the image storage unit 730 newly stores a first image for a predetermined memory chip and the character string extractor 750 extracts the target character string included in the first image, the library recommender 760 may generate recommendation information recommending a parameter page library having the most similar character string value on the basis of the result of comparing the extracted target character string with the parameter page library for each memory chip pre-stored by the library generator 740.

In this case, it may be preferable in a state where the character string value extracted from the memory chip image is pre-stored for each memory chip in the pre-stored parameter page library.

On the basis of the description of the components shown in FIGS. 1 and 2, a method for generating a parameter page library of a NAND flash memory according to the present disclosure will be described with reference to FIGS. 6 to 9.

The method for generating the parameter page library of a NAND flash memory according to an exemplary embodiment of the present disclosure may largely include a step (S100) of obtaining an ID data, a step (S200) of loading a parameter data, a step (S300) of extracting binary data, a step (S400) of assigning a mode classification value, a step (S500) of generating a restoration information, a step (S600) of restoring a memory, and a step (S700) of generating a library.

First, the step (S100) of obtaining the ID data may be for obtaining the ID data of the memory chip 14 after checking and operating the operation voltage of the memory chip 14.

Herein, the ID data may correspond to unique identification information for distinguishing one memory chip from another memory chip, and may include, for example, information such as a manufacturer ID, a manufacturer's identification code, a device ID, and a device identification code.

In the step S100, the initial setting voltage corresponding to a preset voltage level may be applied to the power terminal (VDD) of the memory chip 14, and an initial command value and an initial address value may be inputted to the input/output terminal (I/Ox) of the memory chip 14, thereby obtaining the ID data of the memory chip 14 according to the execution of the ID readout command.

Specifically, as shown in FIG. 7, the step S100 may include a step (S112) of setting the first voltage value as the initial setting voltage (V_{S}), a step (S114) of applying the set initial setting voltage (V_{S}) to the power terminal (VDD) of the memory chip 14, a step (S120) of inputting the initial command (C_{I}) to the input/output terminal (I/Ox) of the memory chip 14, a step (S130) of checking whether the ID data of the memory chip 14 is obtained according to the execution of the ID readout command corresponding to the input of the initial command (C_{I}), a step (S140) of resetting as the initial setting voltage (V_{S}) a second voltage value, which has a voltage level different from the currently set initial setting voltage (V_{S}), among a plurality of voltage levels, when the ID data is not obtained as a checking result, and a step of controlling to repeatedly perform the steps S114, S120, S130, and S140 described above until the ID data is obtained.

Herein, the initial setting voltage (V_{S}) may refer to a voltage for setting the memory chip to be operable, and a plurality of preset voltage levels may include 1.2V, 1.8V, and 3.3V.

Herein, the initial command (C_{I}) may include “90h”, which is an initial command value indicating a readout command (Read ID Command) of the ID data, as shown in FIG. 3.

In the step S130, it may be to check whether the ID data is loaded according to the initial command value (“90h”).

In this case, when it is confirmed that the ID data is obtained, a step (not shown) of storing the voltage value applied to the voltage terminal (VDD) of the memory chip 14, that is, the initial setting voltage (V_{S}) value, as a voltage condition information where the operation and command of the memory chip 14 are executable at the time of obtaining the ID data may be further included.

Next, the step (S200) of loading parameter data may be for loading the parameter data (D_{P}) of the memory chip 14 after checking whether the ID data is obtained in the step S100.

In the step S200, when the ID data is obtained as a checking result of the step S130, the parameter data (D_{P}) stored in the parameter page area may be loaded by inputting a command (C_{P}) for calling the parameter page area of the memory chip 14 to the input/output terminal (I/Ox) of the memory chip 14.

Herein, the command (C_{P}) for calling the parameter page area may include “ECH”, which is a call command value indicating a call command for a parameter page including a manufacturer code (Maker Code) and a device code as shown in FIG. 3.

Next, the step (S300) of extracting the binary data may extract binary data recorded at a specific byte position of the parameter data (D_{P}) loaded in the S200 step.

In this case, it may be preferable that the binary data extracted in the step S300 is first to fourth-byte data of the parameter data (D_{P}).

In addition, a step (S350) of converting the binary data extracted by the step S300 into an ASCII-based character string may be further included.

In this case, the first-byte data, the second-byte data, the third-byte data, and the fourth-byte data of the parameter data (D_{P}) may be converted into a first character string (S1), a second character string (S2), a third character string (S3), and a fourth character string (S4), respectively, by the step S350.

Next, the step (S400) of assigning the mode classification value may be for determining the mode classification value (M) for the memory chip 14 on the basis of the protocol information included in the parameter data (D_{P}).

In the step S400, the mode classification value (M) may be assigned according to a result of comparing the binary data extracted in the step S300 or the character string data converted in the step S350 with the plurality of preset protocol signature information.

Herein, the plurality of protocol signature information may include “ONFI”, an acronym for the Open NAND Flash Interface working group (Open NAND Flash Interface), and “JESD”, an acronym for a memory standard document published by JEDEC (Joint Electron Device Engineering Council).

In the step S400, when the binary data extracted in the step S300 is used as a target for comparison, the first-byte data of the parameter data (D_{P}) may be compared with a respective binary value converted from the first character string “O” and “J” of the protocol signature information, the second-byte data of the parameter data (D_{P}) may be compared with a respective binary value converted from the second character string “N” and “E” of the protocol signature information, the third-byte data of the parameter data (D_{P}) may be compared with a respective binary value converted from the third character string “F” and “S” of the protocol signature information, and the fourth-byte data of the parameter data (D_{P}) may be compared with a respective binary value converted from the fourth character string “I” and “D” of the protocol signature information.

In the step S400, when the character string data converted in the step S350 is used as a target for comparison, the first character string (S1) may be compared with the first character string, “O” and “J”, of the protocol signature information, the second character string (S2) may be compared with the second character string, “N” and “E”, of the protocol signature information, the third character string (S3) may be compared with the third character string, “F” and “S”, of the protocol signature information and the fourth character string (S4) may be compared with the fourth character string, “I” and “D”, of the protocol signature information.

In the step S400, the mode classification value (M) may be assigned as a first classification value when corresponding to “ONFI”, a second classification value when corresponding to “JESD”, and a third classification value when corresponding to neither the first classification value nor the second classification value, according to the comparison result described.

Next, the step (S500) of generating restoration information may generate the parameter page restoration information (I_{R}) by matching the byte-by-byte item value for the corresponding mode classification value (M) and the contents of the parameter data (D_{P}) loaded by the data loader 200 in a byte order on the basis of the parameter page length and the byte-by-byte item value information preset corresponding to the mode classification value (M) assigned in the S400 step.

In this case, a step (not shown) of distinguishing by the classification value and storing the table data of the parameter page corresponding to the first classification value (ONFI) shown in FIG. 4 and the table data of the parameter page corresponding to the second classification value (JESD) shown in FIG. 5 may be further included between the S400 step and the S500 step.

Herein, the table data of the parameter page may be the table data in which the byte number and the item value information are mapped and stored, and the parameter page length may be determined by the last byte number corresponding to the lowest item of the corresponding table.

Next, the step (S600) of restoring the memory may be for restoring the data originally stored in the memory chip 14 on the basis of the parameter page restoration information (I_{R}) generated in the step S500.

In the step S600, the data originally stored in the memory chip 14 may be restored by descrambling through an XOR operation after extracting and recombining the dump data of the memory chip 14 on the basis of the parameter page restoration information (I_{R}).

Specifically, the step S600 may include a step (S612) of extracting the dump data of the memory chip 14 as shown in FIG. 8, a step (S614 to S620) of descrambling through the XOR operation after recombining the extracted dump data on the basis of the parameter page restoration information (I_{R}), and a step (S630) of restoring the data originally stored in the memory chip 14 on the basis of the descrambled data.

Next, the step (S700) of generating the library may be for constructing a library for the parameter page information of the memory chip 14.

In the step S700, the parameter page library (L) may be generated and stored by matching and storing the parameter page restoration information (I_{R}), the initial setting voltage value (V_{S}) applied to the power terminal (VDD) at the time of obtaining the ID data of the memory chip 14, and the mode classification value (M) assigned corresponding to the parameter page.

In this case, a step of obtaining and storing an image by photographing the front of the first memory chip or an image of the front of the first memory chip according to a user input, and a step of extracting a character string included in the image stored corresponding to the first memory chip by using the preset character string extraction algorithm may be further included before the step S700.

Herein the step of obtaining and storing an image by photographing the front of the first memory chip or an image of the front of the first memory chip may be for obtaining and storing the image by photographing the front or bottom of the first memory chip through the camera, or for obtaining and storing an image of the front or bottom of the first memory chip inputted by a user through a user terminal 30.

Herein, the step of extracting a character string included in the image stored corresponding to the first memory chip may be for extracting the character string included in the memory chip image stored in the step of obtaining and storing an image by photographing the front of the first memory chip or an image of the front of the first memory chip by using the preset character string extraction algorithm.

In this case, the step S700 may be for generating and storing the parameter page library (L) for each memory chip by matching and storing the parameter page restoration information (I_{R}) for the first memory chip, the voltage value (V_{S}) applied to the power terminal (VDD) at the time of obtaining the ID data of the first memory chip, the mode classification value (M) assigned corresponding to the parameter page of the first memory chip, and the image stored corresponding to the first memory chip by the step of obtaining and storing an image by photographing the front of the first memory chip or an image of the front of the first memory chip and the step of extracting a character string included in the image stored corresponding to the first memory chip along with the character string value extracted therefrom.

Meanwhile, in the case of a method for generating a parameter page library of a NAND flash memory according to an exemplary embodiment of the present disclosure, the library recommendation process (S730 to S764) shown in FIG. 9 may be further included along with the processes described above.

The library recommendation process may be performed on the premise that each memory chip image and the character string value extracted therefrom are matched and stored in the parameter page library for each memory chip stored in the step S700 and specifically, may include a step (S730) of newly obtaining and storing a first image for a predetermined memory chip, a step (S750) of extracting a target character string included in the stored first image by using the preset character string extraction algorithm, a step (S762) of comparing the extracted target character string with the parameter page library for each memory chip and a step (S764) of generating recommendation information for recommending the parameter page library having the most similar character string value on the basis of the result of comparing the extracted target character string with the parameter page library for each memory chip.

Accordingly, even when the internal controller of the NAND flash memory device is physically damaged or broken and becomes unusable, it is possible to execute the operations and commands of the memory chip, such that the parameter data required for data restoration can be obtained according to the present disclosure.

In addition, according to the present disclosure, a parameter page library can be constructed for each memory chip, so information necessary for data recovery of the corresponding memory can be obtained in a short period of time by using only the memory chip image or the data recorded in the memory chip.

Although the present disclosure has been described in detail through preferred exemplary embodiments, the present disclosure may be not limited thereto and may be implemented in various ways within the scope of the claims.

In particular, since the content described above may explain the features and technical strengths of the present disclosure rather broadly in order to enable a better understanding of the scope of the claims of the present disclosure to be described, it should be recognized by those skilled in the art that the concept and specific exemplary embodiments of the present disclosure described above can be immediately used as a basis for designing or modifying other shapes for carrying out similar purposes to the present disclosure.

In addition, it will be understood that the exemplary embodiment described above is only one exemplary embodiment according to the present disclosure and that it can be implemented in various modified and changed forms within the scope of the technical idea of the present disclosure by a person having ordinary skill in the art. Therefore, the disclosed exemplary embodiment should be considered from an explanatory point of view rather than a limiting point of view, and such various modifications and changes may be also included in the scope of the technical idea of the present disclosure, which is indicated in the claims of the present disclosure described above, and all differences within the equivalent scope should be interpreted as being included in the present disclosure.

### INDUSTRIAL APPLICABILITY

The present disclosure can be utilized in industrial applications for generating a parameter page library for each memory chip according to the readout possibility of a parameter page of the corresponding memory in an environment where an internal controller of a NAND flash memory device is unavailable.

1. A device for generating a library for a parameter page of a memory chip within the memory device in an environment where a memory controller of a NAND flash-type memory device is unavailable, the device comprising:
an ID data acquisition module for obtaining ID data of the memory chip in response to executing an ID readout command by applying an initial setting voltage corresponding to a preset voltage level to a power terminal of the memory chip and then by inputting an initial command value and an initial address value to an input/output terminal of the memory chip;
a data loader for loading parameter data stored in a parameter page area by inputting a call command value and a call address value, which are commands for calling the parameter page area of the memory chip, to the input/output terminal when the ID data is obtained;
a mode classifier for assigning a mode classification value according to a result of extracting and comparing binary data recorded at a specific byte position of the loaded parameter data with a plurality of preset protocol signature information;
a restoration information generator for generating parameter page restoration information by matching the byte-by-byte item value for the corresponding mode classification value and a content of the parameter data in a byte order on the basis of a parameter page length and a byte-by-byte item value information preset corresponding to the assigned-mode classification value; and
a library generator for generating and storing a parameter page library by matching and storing the parameter page restoration information, a voltage value applied to the power terminal at the time of obtaining the ID data, and the mode classification value assigned corresponding to the parameter page.

2. The device of claim 1, wherein the ID data acquisition module comprises:
a voltage applier for setting as the initial setting voltage a first voltage value corresponding to one of a plurality of preset voltage levels and applying the same to the power terminal of the memory chip;
an initial command input unit for inputting an initial command, including the initial command value and the initial address value, to the input/output terminal of the memory chip on the basis of the time point of applying the initial setting voltage;
an execution checker for checking whether the ID data of the memory chip is obtained in response to executing the ID readout command corresponding to an input of the initial command; and
a controller for controlling the voltage applier and the initial command input unit to repeatedly perform an operation of re-inputting the initial command to the input/output terminal until the ID data is obtained after resetting as the initial setting voltage a second voltage value, which has a voltage level different from a currently set initial setting voltage among the plurality of voltage levels, and then applying the same to the power terminal, when the ID data is not obtained.

3. The device of claim 1, further comprising:
a memory restoration module for restoring data originally stored in the memory chip by descrambling through an XOR operation after extracting and recombining dump data of the memory chip on the basis of the parameter page restoration information.

4. The device of claim 1, further comprising:
an image storage unit for obtaining and storing an image by photographing a front of a first memory chip or an image of the front of the first memory chip according to a user input; and
a character string extractor for extracting a character string included in the image stored corresponding to the first memory chip by using a preset character string extraction algorithm,
wherein the library generator generates and stores the parameter page library for each memory chip by matching and storing the parameter page restoration information for the first memory chip, the voltage value applied to the power terminal at the time of obtaining the ID data of the memory chip, and the mode classification value assigned corresponding to the parameter page of the memory chip, and an image stored corresponding to the first memory chip along with a character string value extracted therefrom.

5. The device of claim 4, further comprising:
a library recommender for generating recommendation information recommending the parameter page library, which has a most similar character string value, on the basis of a result of comparing a extracted target character string with the parameter page library for each memory chip when the image storage unit newly stores a first image for a predetermined memory chip and the character string extractor extracts the target character string included in the first image.

6. A method for generating a library for a parameter page of a memory chip within the memory device in an environment where a memory controller of a NAND flash-type memory device is unavailable, the method comprising:
a step of obtaining ID data of the memory chip in response to executing an ID readout command, by applying an initial setting voltage corresponding to a preset voltage level to a power terminal of the memory chip and then by inputting an initial command value and an initial address value to an input/output terminal of the memory chip;
a step of loading parameter data stored in a parameter page area by inputting a call command value and a call address value, which are commands for calling the parameter page area of the memory chip, to the input/output terminal when the ID data is obtained;
a step of assigning a mode classification value according to a result of extracting and comparing binary data recorded at a specific byte position of the loaded parameter data with a plurality of preset protocol signature information;
a step of generating parameter page restoration information by matching a byte-by-byte item value for the corresponding mode classification value and a content of the parameter data in a byte order on the basis of a parameter page length and the byte-by-byte item value information preset corresponding to the assigned-mode classification value; and
a step of generating and storing a parameter page library by matching and storing the parameter page restoration information, a voltage value applied to the power terminal at the time of obtaining the ID data, and the mode classification value assigned corresponding to the parameter page.

7. The method of claim 6, wherein the step of obtaining the ID data comprises:
a step of setting as the initial setting voltage a first voltage value corresponding to one of a plurality of preset voltage levels and applying the same to the power terminal of the memory chip;
a step of inputting an initial command, including the initial command value and the initial address value, to the input/output terminal of the memory chip on the basis of the time point of applying the initial setting voltage;
a step of checking whether the ID data of the memory chip is obtained in response to executing the ID readout command corresponding to an input of the initial command; and
a step of controlling the voltage applier and the initial command input unit to repeatedly perform an operation of re-inputting the initial command to the input/output terminal until the ID data is obtained after resetting as the initial setting voltage a second voltage value, which has a voltage level different from a currently set initial setting voltage among the plurality of voltage levels, and then applying the same to the power terminal, when the ID data is not obtained.

8. The method of claim 6, further comprising:
after the step of generating the parameter page restoration information,
a step of restoring data originally stored in the memory chip by descrambling through an XOR operation after extracting and recombining dump data of the memory chip on the basis of the parameter page restoration information.

9. The method of claim 6, further comprising:
before the step of generating the parameter page library,
a step of obtaining and storing an image by photographing a front of a first memory chip or an image of the front of the first memory chip according to a user input; and
a step of extracting a character string included in the image stored corresponding to the first memory chip by using a preset character string extraction algorithm;
wherein the step of generating the parameter page library generates and stores the parameter page library for each memory chip by matching and storing the parameter page restoration information for the first memory chip, the voltage value applied to the power terminal at the time of obtaining the ID data of the memory chip, and the mode classification value assigned corresponding to the parameter page of the memory chip, and an image stored corresponding to the first memory chip along with a character string value extracted therefrom.

10. The method of claim 9, further comprising:
after the step of generating the parameter page library,
a step of newly obtaining and storing a first image for a predetermined memory chip;
a step of extracting a target character string included in the first image by using a character string extraction algorithm; and
a step of generating recommendation information recommending the parameter page library, which has a most similar character string value, on the basis of a result of comparing an extracted target character string with the parameter page library for each memory chip.
